(19) United States
(12) Patent Application Publication
(10) Pub. No.: US 2018/0175076 A1
(43) Pub. Date: Jun. 21, 2018

(54) TRANSISTOR ARRAY PANEL AND DISPLAY DEVICE INCLUDING THE SAME

(71) Applicant: Samsung Display Co., Ltd., Yongin-si (KR)

(72) Inventors: Eok Su KIM, Seoul (KR); Jay Bum KIM, Seoul (KR); Kyoung Seok SON, Seoul (KR); Jun Hyung LIM, Seoul (KR)

(21) Appl. No.: 15/842,424

(22) Filed: Dec. 14, 2017

(30) Foreign Application Priority Data
Dec. 15, 2016 (KR) 10-2016-0171862

(51) Int. Cl. H01L 27/12; H01L 29/786

(52) U.S. Cl. CPC H01L 27/1251; H01L 27/1225; H01L 27/3262; H01L 29/78675; H01L 29/78645; H01L 29/7869

(57) ABSTRACT

A transistor array panel according to an exemplary embodiment includes: a substrate; a first buffer layer positioned on the substrate; and a first transistor and a second transistor positioned on the substrate and separated from each other, wherein the first transistor includes a polycrystalline semiconductor positioned on the substrate, and a first gate electrode overlapping the polycrystalline semiconductor, the second transistor includes an oxide semiconductor positioned on the first buffer layer, and a second gate electrode overlapping the oxide semiconductor, the first buffer layer covers the first gate electrode, and the first buffer layer includes a silicon oxide.

### CROSS-REFERENCE TO RELATED APPLICATION

This application claims priority to and the benefit of Korean Patent Application No. 10-2016-0171862 filed in the Korean Intellectual Property Office on Dec. 15, 2016, the entire contents of which are incorporated herein by reference.

### BACKGROUND

### 1. Field

The present disclosure relates to a transistor array panel and a display device including the same.

### 2. Description of the Related Art

In general, as a display device, one such as a liquid crystal display (LCD), an organic light emitting diode display (OLED display), and the like are used.

Particularly, the organic light emitting diode display includes two electrodes and an organic light emitting layer positioned therebetween. Electrons injected from a cathode that is an electrode and holes injected from an anode that is another electrode are bonded to each other in the organic light emitting layer to form excitons. Light is emitted while the excitons discharge energy.

The organic light emitting diode display includes a plurality of pixels including an organic light emitting diode made of a cathode, an anode, and an organic emission layer. In each pixel, a plurality of transistors and a capacitor to drive the organic light emitting diode are formed.

The transistor includes a gate electrode, a source electrode, a drain electrode, and a semiconductor. The semiconductor is an important factor in determining characteristics of the transistor. The semiconductor mainly includes silicon (Si). The silicon is divided into amorphous silicon and polysilicon according to a crystallization type, wherein the amorphous silicon has a simple manufacturing process but has low charge mobility such that there is a limit for manufacturing a high performance thin film transistor, and the polysilicon has high charge mobility but a process of crystallizing the silicon is required such that the manufacturing cost is increased and the process is complicated. Recently, studies on a thin film transistor using an oxide semiconductor with a higher on/off ratio and higher carrier mobility than the amorphous silicon, and lower cost and higher uniformity than polycrystalline silicon, have progressed.

However, the characteristics of the oxide semiconductor may be changed by hydrogen inflowed from other adjacent insulating layers.

The above information disclosed in this Background section is only for enhancement of understanding of the background of the disclosure and therefore it may contain information that does not form the prior art that is already known in this country to a person of ordinary skill in the art.

### SUMMARY

An exemplary embodiment provides a transistor array panel preventing the characteristic change of the transistor, and a display device including the same.

A transistor array panel according to an exemplary embodiment includes: a substrate; a first buffer layer positioned on the substrate; and a first transistor and a second transistor positioned on the substrate and separated from each other, wherein the first transistor includes a polycrystalline semiconductor positioned on the substrate, and a first gate electrode overlapping the polycrystalline semiconductor, the second transistor includes an oxide semiconductor positioned on the first buffer layer, and a second gate electrode overlapping the oxide semiconductor, wherein the first buffer layer covers the first gate electrode, and the first buffer layer includes a silicon oxide.

A first insulating layer positioned between the polycrystalline semiconductor and the first gate electrode, a second insulating layer positioned on the first buffer layer, and an insulating member positioned between the oxide semiconductor and the second gate electrode may be further included, and wherein the second insulating layer and the insulating member may include the same material.

A third insulating layer positioned on the second insulating layer and the second gate electrode may be further included, wherein the first transistor may further include a first source electrode and a first drain electrode that are positioned on the third insulating layer and are connected to the polycrystalline semiconductor, and the second transistor may further include a second source electrode and a second drain electrode that are positioned on the third insulating layer and are connected to the oxide semiconductor.

A second buffer layer positioned between the substrate and the polycrystalline semiconductor may be further included, and wherein the second buffer layer may include a silicon nitride.

The second buffer layer may extend to a bottom of the first buffer layer, and the second buffer layer may include a silicon nitride.

The first insulating layer may extend to a bottom of the first buffer layer, and the first insulating layer may include a silicon nitride.

A storage electrode overlapping the first gate electrode, and a storage layer positioned between the first gate electrode and the storage electrode may be further included, and the storage electrode may be positioned under the first buffer layer.

A transistor array panel according to another exemplary embodiment includes: a substrate; a first buffer layer positioned on the substrate; a second buffer layer positioned on the first buffer layer; and a first transistor and a second transistor positioned on the first buffer layer and separated from each other, wherein the first transistor includes a polycrystalline semiconductor positioned on the second buffer layer, and a first gate electrode overlapping the polycrystalline semiconductor, the second transistor includes an oxide semiconductor positioned on the first buffer layer, and a second gate electrode overlapping the oxide semiconductor, wherein the second buffer layer covers the second gate electrode, and the first buffer layer includes a silicon oxide.

A first insulating layer positioned between the polycrystalline semiconductor and the first gate electrode, and an insulating member positioned between the oxide semiconductor and the second gate electrode may be further included, and wherein the insulating member may be positioned under the first insulating layer.

A third insulating layer covering the first insulating layer and the first gate electrode may be further included, wherein the first transistor may further include a first source electrode and a first drain electrode that are positioned on the third insulating layer and are connected to the polycrystalline semiconductor, and the second transistor may further include a second source electrode and a second drain electrode that are positioned on the third insulating layer and are connected to the oxide semiconductor.

The second buffer layer may include a silicon nitride.

A storage electrode overlapping the first gate electrode, and a storage layer positioned between the first gate electrode and wherein the storage electrode may be further included, and the storage electrode may be positioned under the third insulating layer.

A display device according to another exemplary embodiment includes: a substrate; a first buffer layer positioned on the substrate; a first transistor and a second transistor positioned on the substrate and separated from each other; a first electrode connected to one of the first transistor and the second transistor; a second electrode facing the first electrode; and a light emission member positioned between the first electrode and the second electrode, wherein the first transistor includes a polycrystalline semiconductor positioned on the substrate, and a first gate electrode overlapping the polycrystalline semiconductor, the second transistor includes an oxide semiconductor positioned on the first buffer layer, and a second gate electrode overlapping the oxide semiconductor, wherein the first buffer layer covers the first gate electrode, and the first buffer layer includes a silicon oxide.

A first insulating layer positioned between the polycrystalline semiconductor and the first gate electrode, a second insulating layer positioned on the first buffer layer, and an insulating member positioned between the oxide semiconductor and the second gate electrode may be further included, and wherein the second insulating layer and the insulating member may include the same material.

According to an exemplary embodiment, hydrogen may be prevented from inflowing into the oxide semiconductor, thereby preventing the characteristic change of the transistor.

### BRIEF DESCRIPTION OF THE DRAWINGS

FIG. 1 is a cross-sectional view of a transistor array panel according to an exemplary embodiment.

FIG. 2 is a graph of a drain current IDS depending on a gate voltage Vcs in a transistor array panel of a comparative example.

FIG. 3 is a graph of a drain current IDs depending on a gate voltage Vcs in a transistor array panel shown in FIG. 1.

FIG. 4 is a cross-sectional view of a transistor array panel according to another exemplary embodiment.

FIG. 5 is a cross-sectional view of a transistor array panel according to another exemplary embodiment.

FIG. 6 is a cross-sectional view of a transistor array panel according to another exemplary embodiment.

FIG. 7 is an equivalent circuit diagram of a display device including a transistor array panel shown in FIG. 1.

FIG. 8 is a cross-sectional view of a display device of FIG. 7.

FIG. 9 is a cross-sectional view of a display device according to another exemplary embodiment.

### DETAILED DESCRIPTION OF THE EMBODIMENTS

The present disclosure will be described more fully hereinafter with reference to the accompanying drawings, in which exemplary embodiments of the invention are shown. As those skilled in the art would realize, the described embodiments may be modified in various different ways, all without departing from the spirit or scope of the present disclosure.

In order to clearly explain the present disclosure, a portion that is not directly related to the present disclosure was omitted, and the same reference numerals are attached to the same or similar constituent elements through the entire specification.

In addition, the size and thickness of each configuration shown in the drawings are arbitrarily shown for better understanding and ease of description, but the present disclosure is not limited thereto.

In the drawings, the thickness of layers, films, panels, regions, etc., are exaggerated for clarity. In the drawings, for better understanding and ease of description, the thicknesses of some layers and areas are exaggerated. It will be understood that when an element such as a layer, film, region, or substrate is referred to as being “on” another element, it can be directly on the other element or intervening elements may also be present.

Further, in the specification, the phrase “in a plane view” means viewing the object portion from the top, and the phrase “on a cross-section” means viewing a cross-section of which the object portion is vertically cut from the side.

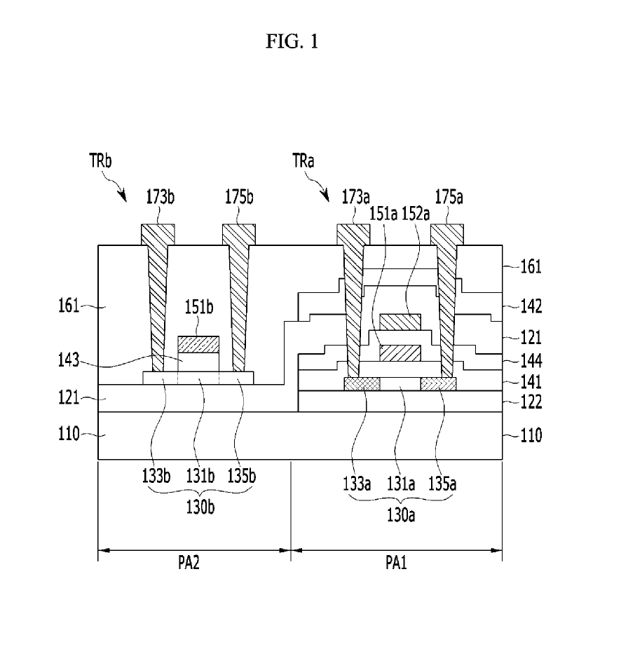

FIG. 1 is a cross-sectional view of a transistor array panel according to an exemplary embodiment.

Referring to FIG. 1, the transistor array panel according to an exemplary embodiment includes a substrate 110, a first buffer layer 121 positioned on the substrate 110, and a first transistor TRa and a second transistor TRb positioned on the substrate 110 and separated from each other.

The substrate 110 may include an insulation substrate made of glass, quartz, a ceramic material, or a plastic material.

The first buffer layer 121 is contact with the substrate 110 and covers a part of the substrate 110. The first buffer layer 121 may include a silicon oxide (SiOx). However, a material of the first buffer layer 121 is not limited thereto, and when the first buffer layer 121 is formed of a dual layer, a lower layer may include a silicon nitride (SiNx) and an upper layer may include a silicon oxide (SiOx). The first buffer layer 121 serves to planarize a surface while preventing unnecessary materials such as impurities or moisture from permeating.

The first transistor TRa includes a polycrystalline semiconductor 130a positioned on the substrate 110, a first gate electrode 151a overlapping the polycrystalline semiconductor 130a, and a first source electrode 173a and a first drain electrode 175a that are connected to the polycrystalline semiconductor 130a. The polycrystalline semiconductor 130a may include a polysilicon made through a process of crystallizing amorphous silicon.

Also, the second transistor TRb includes an oxide semiconductor 130b positioned on the first buffer layer 121, a second gate electrode 151b overlapping the oxide semiconductor 130b, and a second source electrode 173b and a second drain electrode 175b that are connected to the oxide semiconductor 130b. The first buffer layer 121 is only positioned between the oxide semiconductor 130b and the substrate 110.

The first buffer layer 121 including a silicon oxide (SiOx) is positioned and the insulating layer including a silicon nitride (SiNx) is not positioned under the oxide semiconductor 130b of the second transistor TRb. The first buffer layer 121 including a silicon oxide (SiOx) has a small content of hydrogen (H) such that hydrogen inflowing to the oxide semiconductor 130b may be minimized. Accordingly, the characteristic change of the second transistor TRb may be minimized.

Hereinafter, the layered structure of the transistor array panel is described in detail.

The substrate 110 is divided into a first region PA1 where the first transistor TRa is positioned and a second region PA2 where the second transistor TRb is positioned.

The first region PA1 is firstly described, and the second region PA2 is secondly described.

A second buffer layer 122 is positioned on the substrate 110 in the first region PA1. The second buffer layer 122 may include an inorganic insulating material such as a silicon oxide (SiOx), a silicon nitride (SiNx), etc. The second buffer layer 122 may be a single layer or a multilayer. For example, when the second buffer layer 122 is a dual layer, the lower layer may include a silicon nitride (SiNx) and the upper layer may include a silicon oxide (SiOx).

Also, the polycrystalline semiconductor 130a is positioned on the second buffer layer 122. The polycrystalline semiconductor 130a includes a source region 133a connected to the source electrode 173a, a drain region 135a connected to the drain electrode 175a, and a channel region 131a positioned between the source region 133a and the drain region 135a. The source region 133a and the drain region 135a are doped with the impurity to be conductive.

A first insulating layer 141 is positioned on the polycrystalline semiconductor 130a. The first insulating layer 141 may include the insulating material such as a silicon oxide (SiOx) or a silicon nitride (SiNx).

The first gate electrode 151a overlapping the channel region 131a of the polycrystalline semiconductor 130a is positioned on the first insulating layer 141. The first gate electrode 151a may include any one among copper (Cu), copper alloys, aluminum (Al), aluminum alloys, molybdenum (Mo), and molybdenum alloys.

A storage layer 144 and a storage electrode 152a are sequentially positioned on the first gate electrode 151a. The storage layer 144 may include the insulating material such as a silicon oxide (SiOx), a silicon nitride (SiNx), etc. The storage electrode 152a may include any one among copper (Cu), copper alloys, aluminum (Al), aluminum alloys, molybdenum (Mo), and molybdenum alloys.

The storage layer 144 is positioned between the first gate electrode 151a and the storage electrode 152a. Accordingly, the storage electrode 152a overlaps the first gate electrode 151a, thereby forming a storage capacitor Cst.

The first buffer layer 121 is positioned on the storage electrode 152a.

The first buffer layer 121 is positioned at both of the first region PA1 and the second region PA2 and extends from the second region PA2 to the first region PA1, thereby covering the storage electrode 152a.

A second insulating layer 142 is positioned on the first buffer layer 121 positioned at the first region PA1. The second insulating layer 142 may include the insulating material such as a silicon oxide (SiOx), a silicon nitride (SiNx), etc.

A third insulating layer 161 is positioned on the second insulating layer 142 positioned at the first region PA1. The first source electrode 173a connected to the source region 133a of the polycrystalline semiconductor 130a and the first drain electrode 175a connected to the drain region 135a of the polycrystalline semiconductor 130a are formed on the third insulating layer 161.

The first source electrode 173a and the first drain electrode 175a may be formed of a multilayer in which a metal layer including any one among copper (Cu), copper alloys, aluminum (Al), aluminum alloys, molybdenum (Mo), and molybdenum alloys is stacked.

On the other hand, the oxide semiconductor 130b is positioned on the first buffer layer 121 at the second region PA2. The oxide semiconductor 130b includes a source region 133b connected to the second source electrode 173b, a drain region 135b connected to the second drain electrode 175b, and a channel region 131b positioned between the source region 133b and the drain region 135b. The oxide semiconductor 130b may include oxides of metals such as zinc (Zn), indium (In), gallium (Ga), tin (Sn), and titanium (Ti), or metals such as zinc (Zn), indium (In), gallium (Ga), tin (Sn), and titanium (Ti), and a combination thereof. In further detail, the oxide may include at least one of zinc oxide (ZnO), zinc-tin oxide (ZTO), zinc-indium oxide (ZIO), indium oxide (InO), titanium oxide (TiO), indium-gallium-zinc oxide (IGZO), and indium-zinc-tin oxide (IZTO).

An insulating member 143 is formed at a position overlapping the channel region 131b on the oxide semiconductor 130b. The insulating member 143 may be formed of the same material as the second insulating layer 142 in the same manufacturing process as that of the second insulating layer 142. Since the insulating member 143 does not cover the source region 133b and the drain region 135b, the third insulating layer 161 is in direct contact with the source region 133b and the drain region 135b. Accordingly, because hydrogen (H) inflowed from the adjacent third insulating layer 161 is diffused in the source region 133b and the drain region 135b, the source region 133b and the drain region 135b are conductive.

The second gate electrode 151b is positioned on the insulating member 143. The second gate electrode 151b may include any one among copper (Cu), copper alloys, aluminum (Al), aluminum alloys, molybdenum (Mo), and molybdenum alloys.

The third insulating layer 161 is also positioned on the second gate electrode 151b positioned at the second region PA2, the oxide semiconductor 130b, and the first buffer layer 121. The second source electrode 173b connected to the source region 133b of the oxide semiconductor 130b and the second drain electrode 175b connected to the drain region 135b of the oxide semiconductor 130b are positioned on the third insulating layer 161 positioned at the second region PA2.

The second source electrode 173b and the second drain electrode 175b may be formed of a multilayer in which a metal layer including any one among copper (Cu), copper alloys, aluminum (Al), aluminum alloys, molybdenum (Mo), and molybdenum alloys is stacked.

As above-described, the first buffer layer 121 including a silicon oxide (SiOx) is positioned and the first insulating layer 141, and the storage layer 144 including a silicon nitride (SiNx) are not positioned under the oxide semiconductor 130b of the second transistor TRb. The content of hydrogen is high in the first insulating layer 141 and the storage layer 144 including a silicon nitride (SiNx). Accordingly, it is difficult for hydrogen to inflow from the first insulating layer 141 and the storage layer 144 to the oxide semiconductor 130b.

Also, the content of hydrogen is small in the first buffer layer 121 including a silicon oxide (SiOx) such that it is possible to minimize the flow of hydrogen into the oxide semiconductor 130b. Accordingly, the characteristic change of the second transistor TRb may be prevented and uniformity of the transistor may be improved.

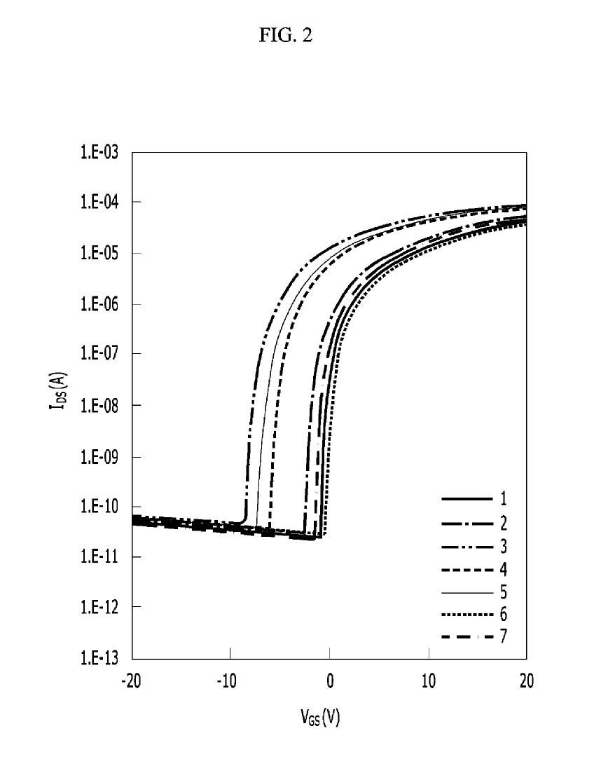

FIG. 2 is a graph of a drain current IDs depending on a gate voltage Vcs in a transistor array panel of a comparative example. In the transistor array panel (not shown) of the comparative example, the first insulating layer including a silicon nitride (SiNx) is positioned under the oxide semiconductor. Seven curves displayed in the graph of FIG. 2 are characteristic curves of transistors presented at various positions in the transistor array panel.

As shown in FIG. 2, in the transistor array panel of the comparative example, the characteristic graph of the drain current IDS depending on the gate voltage Vcs is differentiated, thereby not being uniform. That is the reason that the oxide semiconductor 130b changes the characteristic of the transistor by hydrogen inflowed from the adjacent first insulating layer 141.

However, in the transistor array panel according to an exemplary embodiment, as the first insulating layer including a silicon nitride (SiNx) is removed under the oxide semiconductor 130b, the change of the transistor characteristic may be minimized.

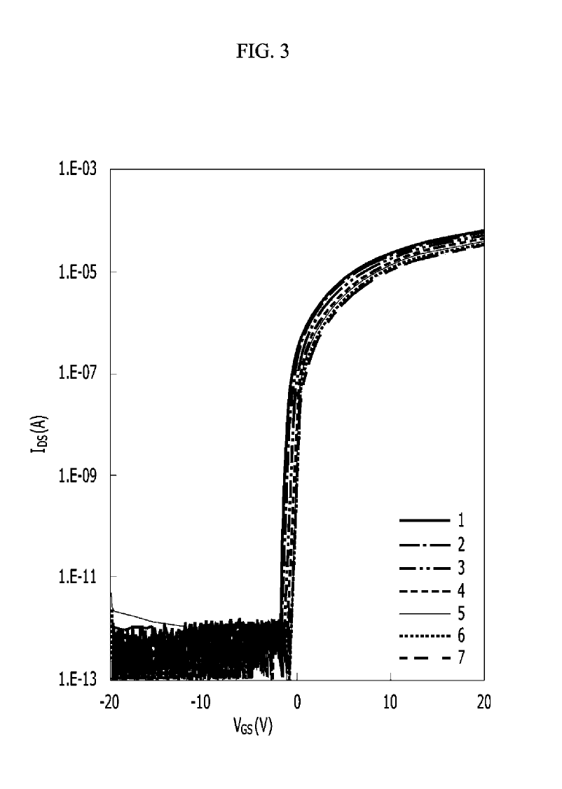

FIG. 3 is a graph of a drain current IDS depending on a gate voltage Vcs in a transistor array panel shown in FIG. 1.

As shown in FIG. 3, in the transistor array panel according to an exemplary embodiment, the characteristic graph drain current IDS depending on the gate voltage Vcs has almost no change for each position, thereby being uniform.

In the exemplary embodiment described in FIG. 1, only the first buffer layer and not the second buffer layer is positioned under the oxide semiconductor; however the first buffer layer and the second buffer layer may also be positioned under the oxide semiconductor as another exemplary embodiment.

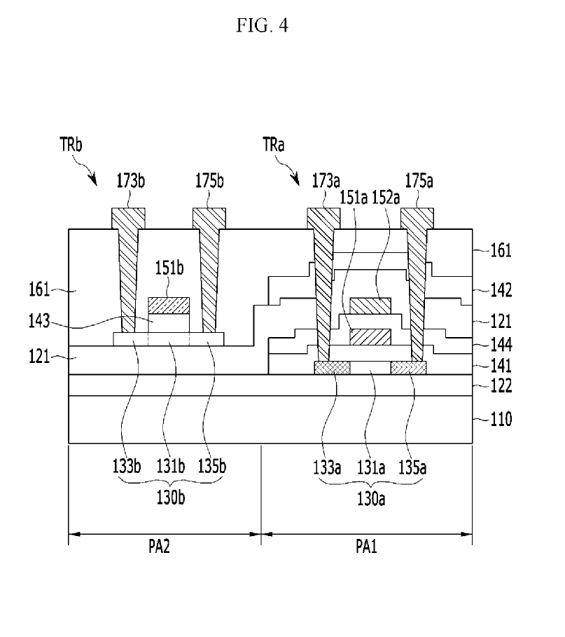

Hereinafter, the transistor array panel according to another exemplary embodiment of the present disclosure will be described with reference to FIG. 4.

FIG. 4 is a cross-sectional view of a transistor array panel according to another exemplary embodiment.

The exemplary embodiment shown in FIG. 4 is substantially the same as the exemplary embodiment shown in FIG. 1 except for the structure of the second buffer layer such that the repeated description is omitted.

As shown in FIG. 4, in the transistor array panel according to another exemplary embodiment of the present disclosure, the second buffer layer 122 extends to a bottom of the first buffer layer 121. Accordingly, in the second region PA2, the first buffer layer 121 and the second buffer layer 122 are positioned under the oxide semiconductor 130b.

The second buffer layer 122 includes the inorganic insulating material such as a silicon oxide (SiOx), a silicon nitride (SiNx), etc., however the first buffer layer 121 includes a silicon oxide (SiOx). The silicon oxide (SiOx) may be positioned in the portion where the oxide semiconductor 130b and the first buffer layer 121 are in contact. When the first buffer layer 121 is the dual layer, the lower layer may include a silicon nitride (SiNx) and the upper layer may include a silicon oxide (SiOx).

Accordingly, since the content of hydrogen (H) is small in the first buffer layer 121 including a silicon oxide (SiOx), it is possible to minimize the inflow of hydrogen into the oxide semiconductor 130b. Accordingly, the characteristic change of the second transistor TRb may be minimized.

The characteristics of the thin film transistor according to the exemplary embodiment described with reference to FIG. 1 except for the position of the second buffer layer 122 may be applied to the transistor array panel according to the present exemplary embodiment.

Though only the first buffer layer and the second buffer layer are positioned under the oxide semiconductor in the present exemplary embodiment described in FIG. 4, and not the first insulating layer, all of the first buffer layer, the second buffer layer, and the first insulating layer may also be positioned under the oxide semiconductor as another exemplary embodiment.

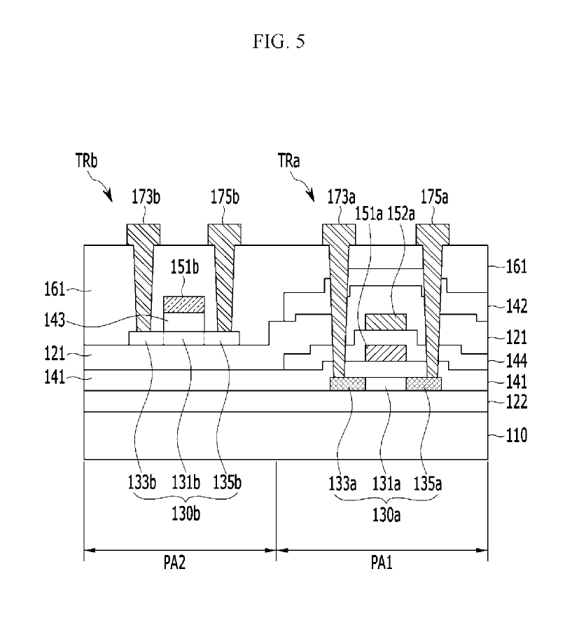

Next, the transistor array panel according to another exemplary embodiment of the present disclosure will be described with reference to FIG. 5.

FIG. 5 is a cross-sectional view of a transistor array panel according to another exemplary embodiment.

The exemplary embodiment shown in FIG. 5 is substantially the same as the exemplary embodiment shown in FIG. 4 except for the first insulating layer such that the repeated description is omitted.

As shown in FIG. 5, in the transistor array panel according to another exemplary embodiment of the present disclosure, the first insulating layer 141 extends to the bottom of the first buffer layer 121. Accordingly, in the second region PA2, the first buffer layer 121, the second buffer layer 122, and the first insulating layer 141 are positioned under the oxide semiconductor 130b.

The first insulating layer 141 includes the inorganic insulating material such as a silicon oxide (SiOx), a silicon nitride (SiNx), etc., however the first buffer layer 121 includes a silicon oxide (SiOx). The silicon oxide (SiOx) may be positioned at the portion where the oxide semiconductor 130b and the first buffer layer 121 are in contact.

Since the content of hydrogen (H) is small in the first buffer layer 121 including a silicon oxide (SiOx), it is possible to minimize the inflow of hydrogen into the oxide semiconductor 130b. Accordingly, the characteristic change of the second transistor TRb may be minimized.

The characteristics of the thin film transistors according to the exemplary embodiments described with reference to FIG. 1 and FIG. 4 may be applied to the thin film transistor array panel according to the present exemplary embodiment except for the position of the first buffer layer 121, the second buffer layer 122, and the first insulating layer 141.

Though in the exemplary embodiment described in FIG. 5 the second transistor is formed after forming the first transistor, the first buffer layer is positioned on the polycrystalline semiconductor and the oxide semiconductor is positioned on the first buffer layer, another exemplary embodiment is possible in which the first transistor is formed after forming the second transistor to position the second buffer layer on the oxide semiconductor and to position the polycrystalline semiconductor on the second buffer layer.

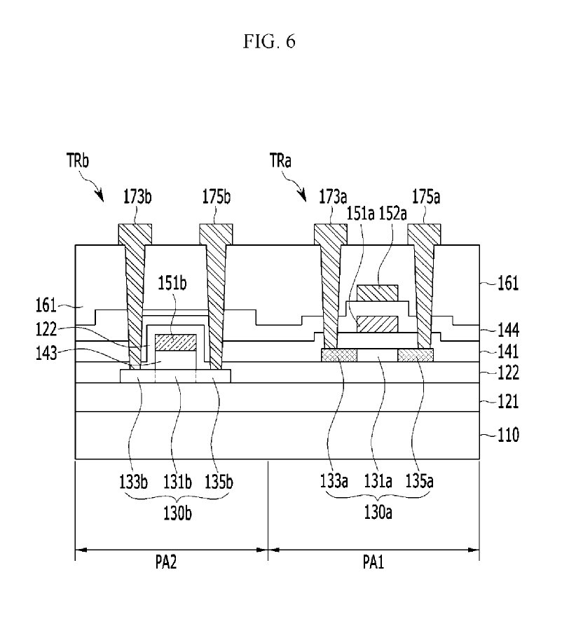

Next, the transistor array panel according to another exemplary embodiment of the present disclosure will be described with reference to FIG. 6.

FIG. 6 is a cross-sectional view of a transistor array panel according to another exemplary embodiment.

The exemplary embodiment shown in FIG. 6 is substantially the same as the exemplary embodiment shown in FIG. 1 except for the structure of the first buffer layer, the second buffer layer, and the second insulating layer such that the repeated description is omitted.

As shown in FIG. 6, the transistor array panel according to another exemplary embodiment of the present disclosure includes the substrate 110, the first buffer layer 121 positioned on the substrate 110, the second buffer layer 122 positioned on the first buffer layer 121, and the first transistor TRa and the second transistor TRb positioned on the first buffer layer 121 and separated from each other.

The first buffer layer 121 covers the entire substrate 110. The first buffer layer 121 may include a silicon oxide (SiOx). However, a material of the first buffer layer 121 is not limited thereto, and when the first buffer layer 121 is formed of a dual layer, a lower layer may include a silicon nitride (SiNx) and an upper layer may include a silicon oxide (SiOx).

The second buffer layer 122 covers part of the first buffer layer 121. The second buffer layer 122 may include the inorganic insulating material such as a silicon oxide (SiOx), a silicon nitride (SiNx), etc.

The first transistor TRa includes the polycrystalline semiconductor 130a positioned on the substrate 110, the first gate electrode 151a overlapping the polycrystalline semiconductor 130a, and the first source electrode 173a and the first drain electrode 175a that are connected to the polycrystalline semiconductor 130a.

Also, the second transistor TRb includes the oxide semiconductor 130b positioned on the first buffer layer 121, the second gate electrode 151b overlapping the oxide semiconductor 130b, and the second source electrode 173b and the second drain electrode 175b that are connected to the oxide semiconductor 130b.

The first buffer layer 121 including a silicon oxide (SiOx) is positioned under the oxide semiconductor 130b of the second transistor TRb. Since the content of hydrogen (H) is small in the first buffer layer 121 including a silicon oxide (SiOx), it is possible to minimize the inflow of hydrogen into the oxide semiconductor 130b. Accordingly, the characteristic change of the second transistor TRb may be minimized.

Next, the layered structure of the transistor array panel will be described in detail. Hereinafter, the layered structure of the transistor array panel is described in detail.

In the first region PAL the first buffer layer 121 is positioned on the substrate 110, and the second buffer layer 122 is positioned on the first buffer layer 121. The polycrystalline semiconductor 130a is positioned on the second buffer layer 122.

The first insulating layer 141 is positioned on the polycrystalline semiconductor 130a. The first insulating layer 141 may include the insulating material such as a silicon oxide (SiOx), a silicon nitride (SiNx), etc.

The first gate electrode 151a overlapping the channel region 131a of the polycrystalline semiconductor 130a is positioned on the first insulating layer 141.

The storage layer 144 and the storage electrode 152a are sequentially positioned on the first gate electrode 151a. The storage layer 144 may include the insulating material such as a silicon oxide (SiOx), a silicon nitride (SiNx), etc. The storage layer 144 is positioned between the first gate electrode 151a and the storage electrode 152a. Accordingly, the storage electrode 152a overlaps the first gate electrode 151a, thereby forming the storage capacitor Cst.

The third insulating layer 161 is positioned on the storage electrode 152a and the storage layer 144 that are positioned at the first region PA1. The first source electrode 173a and the first drain electrode 175a are positioned on the third insulating layer 161.

On the other hand, the oxide semiconductor 130b is positioned on the first buffer layer 121 positioned at the second region PA2. The oxide semiconductor 130b includes the source region 133b connected to the second source electrode 173b, the drain region 135b connected to the second drain electrode 175b, and the channel region 131b positioned between the source region 133b and the drain region 135b.

The insulating member 143 is positioned at the position overlapping the channel region 131b on the oxide semiconductor 130b. The second gate electrode 151b is positioned on the insulating member 143.

The second buffer layer 122 is positioned on the second gate electrode 151b and the oxide semiconductor 130b. The first insulating layer 141 is positioned on the second buffer layer 122. Also, the storage layer 144 is positioned on the first insulating layer 141 and the third insulating layer 161 is positioned on the storage layer 144.

The second source electrode 173b and the second drain electrode 175b are positioned on the third insulating layer 161 positioned at the second region PA2.

As described above, as the first transistor TRa is formed after forming the second transistor TRb, the first buffer layer 121 including a silicon oxide (SiOx) is only positioned under the oxide semiconductor 130b of the second transistor TRb. Accordingly, since the first buffer layer 121 including a silicon oxide (SiOx) has the small content of hydrogen, hydrogen may be minimized from inflowing into the oxide semiconductor 130b. Accordingly, the characteristic change of the second transistor TRb may be prevented and the uniformity of the transistor may be improved.

The characteristics of the thin film transistors according to the exemplary embodiments described with reference to FIG. 1, FIG. 4, and FIG. 5 except for the positions of the first buffer layer, the second buffer layer, and the second insulating layer may all be applied to the thin film transistor array panel according to the present exemplary embodiment.

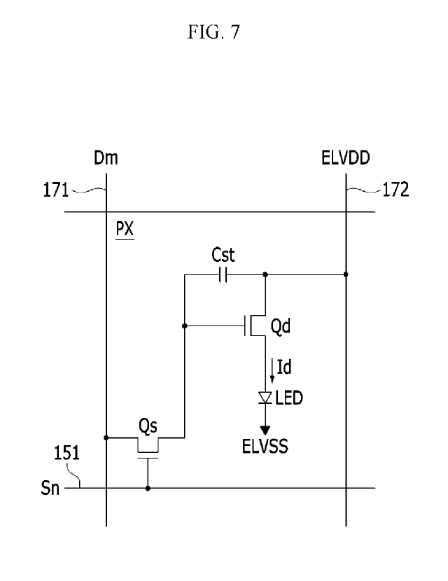

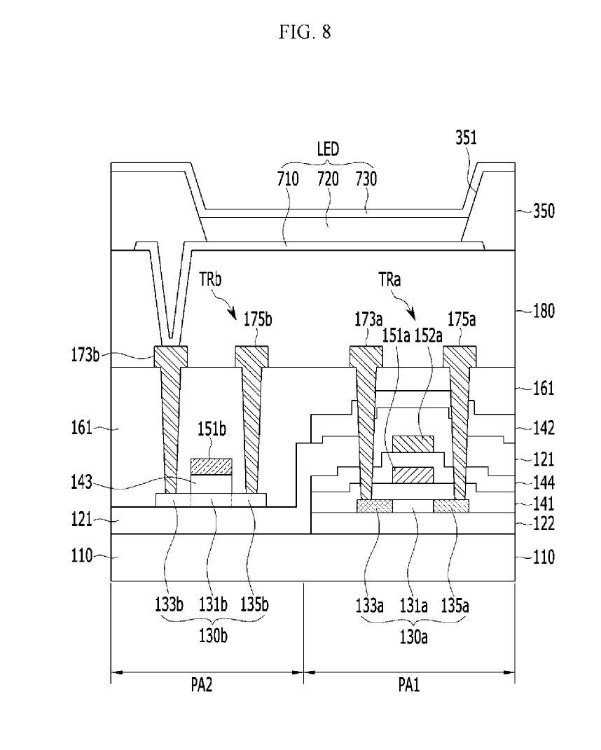

Next, the display device including the transistor array panel according to another exemplary embodiment will be described with reference to FIG. 7 and FIG. 8.

FIG. 7 is an equivalent circuit diagram of a display device including a transistor array panel shown in FIG. 1.

The display device according to the present exemplary embodiment is a light emissive display, and may include the transistor array panel according to the above-described exemplary embodiment.

As shown in FIG. 7, one pixel PX of the display device including the transistor array panel according to an exemplary embodiment includes a plurality of signal lines 151, 171, and 172, and a plurality of transistors Qs and Qd, a storage capacitor Cst, and a light emission diode (LED) that are connected to the plurality of signal lines 151, 171, and 172.

The plurality of signal lines 151, 171, and 172 include a scan line 151 transmitting a scan signal Sn, a data line 171 transmitting a data signal Dm, and a driving voltage line 172 transmitting a driving voltage ELVDD.

The plurality of transistors Qd and Qs include a driving transistor Qd and a switching transistor Qs. The transistor according to the present exemplary embodiment may be applied to the driving transistor Qd or the switching transistor Qs.

The switching transistor Qs includes a control terminal, an input terminal, and an output terminal. The control terminal is connected to the scan line 151, the input terminal is connected to the data line 171, and the output terminal is connected to the driving transistor Qd. The switching transistor Qs transmits the data signal Dm applied to the data line 171 to the driving transistor Qd in response to the scan signal Sn applied to the scan line 151.

The driving transistor Qd also has a control terminal, an input terminal, and an output terminal, the control terminal is connected to the switching transistor Qs, the input terminal is connected to the driving voltage line 172, and the output terminal is connected to the light emission diode (LED). The driving transistor Qd flows a driving current Id having a magnitude that is changed depending on a voltage applied between the control terminal and the output terminal.

The storage capacitor Cst is connected between the control terminal and the output terminal of the driving transistor Qd. The storage capacitor Cst is charged by a data signal applied to the control terminal of the driving transistor Qd, and maintains a charge even after the switching transistor Qs is turned off.

The light emission diode LED includes an anode connected to the output terminal of the driving transistor Qd and a cathode connected to the common voltage ELVSS. The light emission diode LED displays an image by emitting light with variable intensity according to the output current Id of the driving transistor Qd.

In the present exemplary embodiment, the switching transistor Qs and the driving transistor Qd are n-channel field effect transistors (FET), but they are not limited thereto, and they may be p-channel field effect transistors. The transistors Qs and Qd, the storage capacitor Cst, and the light emission diode LED may be variously connected. The detailed structure of the display device shown in FIG. 7 will be described with reference to FIG. 8.

FIG. 8 is a cross-sectional view of a display device of FIG. 7.

As shown in FIG. 8, the display device according to an exemplary embodiment includes the substrate 110, the first buffer layer 121 positioned at the second region PA2 on the substrate 110, the second buffer layer 122 positioned at the first region PA1 on the substrate 110, and the first transistor TRa and the second transistor TRb respectively positioned on the second buffer layer 122 and the first buffer layer 121 and separated from each other.

The oxide semiconductor 130b is positioned on the first buffer layer 121, and the polycrystalline semiconductor 130a is positioned on the second buffer layer 122.

Accordingly, the first buffer layer 121 including a silicon oxide (SiOx) is only positioned under the oxide semiconductor 130b of the second transistor TRb such that hydrogen may be minimized from inflowing into the oxide semiconductor 130b. Accordingly, the characteristic change of the second transistor TRb may be minimized.

In the present exemplary embodiment, the second transistor TRb may be the driving transistor Qd. A passivation layer 180 covering the second transistor TRb is positioned thereon. A pixel electrode 710 as a first electrode is positioned on the passivation layer 150, and the pixel electrode 710 may include a transparent conductive material such as indium tin oxide (ITO), indium zinc oxide (IZO), zinc oxide (ZnO), or indium oxide (In2O3), or a reflective metal material such as lithium (Li), calcium (Ca), lithium fluoride/calcium (LiF/Ca), lithium fluoride/aluminum (LiF/Al), aluminum (Al), silver (Ag), magnesium (Mg), or gold (Au). The pixel electrode 710 is electrically connected to the second source electrode 173b of the second transistor TRb, thereby being an anode of the light emitting diode (LED).

A pixel definition layer 350 is positioned on the passivation layer 180 and an edge portion of the pixel electrode 710. The pixel definition layer 350 has a pixel opening 351 overlapping the pixel electrode 710. The pixel definition layer 350 may include a resin such as a polyacrylate resin and a polyimide resin, or a silica-based inorganic material.

An organic emission layer 720 is positioned in the pixel opening 351 of the pixel definition layer 350. The light emission member 720 may include a plurality of layers including at least one of a light emission layer, a hole injection layer (HIL), a hole transporting layer (HTL), an electron transporting layer (ETL), and an electron injection layer (EIL). The light emission layer may be an organic material or an inorganic material. When the emission member 720 includes all of the layers, the hole injection layer may be positioned on the pixel electrode 710 corresponding to an anode, and the hole transporting layer, the emission layer, the electron transporting layer, and the electron injection layer may be sequentially stacked.

Also, a common electrode 730 is positioned on the pixel definition layer 350 and the light emission member 720. The common electrode 730 may include a transparent conductive material such as indium tin oxide (ITO), indium zinc oxide (IZO), zinc oxide (ZnO), or indium oxide (In2O3), or a reflective metal material such as lithium (Li), calcium (Ca), lithium fluoride/calcium (LiF/Ca), lithium fluoride/aluminum (LiF/Al), aluminum (Al), silver (Ag), magnesium (Mg), or gold (Au). The common electrode 730 becomes a cathode of the light emitting diode (LED). The pixel electrode 710, the light emission member 720, and the common electrode 730 form the light emitting diode (LED).

The display device according to the exemplary embodiment shown in FIG. 8 includes the thin film transistor array panel according to the exemplary embodiment shown in FIG. 1, however the display device according to another exemplary embodiment of the present disclosure may include the thin film transistor array panel according to the exemplary embodiments shown in FIG. 4, FIG. 5, or FIG. 6.

On the other hand, in the display device shown in FIG. 8, the second transistor TRb is the driving transistor Qd, however the second transistor TRa may be the switching transistor Qs as another exemplary embodiment.

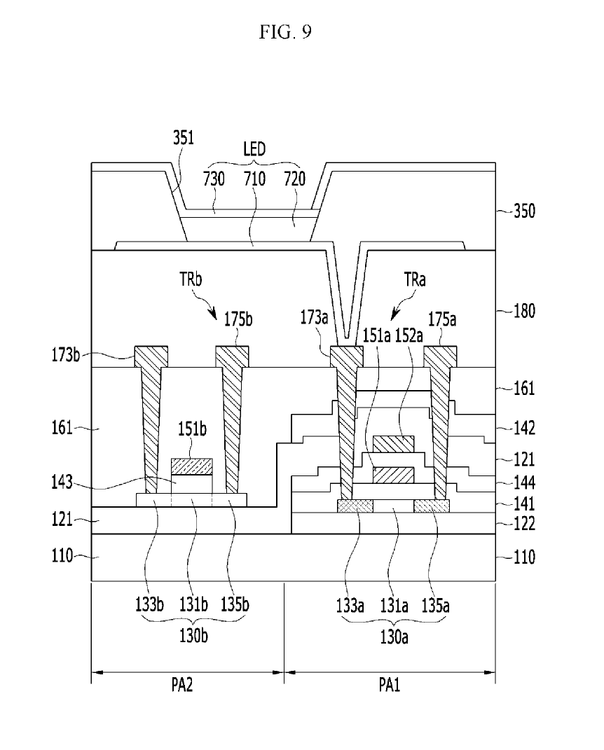

Next, the display device according to another exemplary embodiment of the present disclosure will be described in detail with reference to FIG. 9.

FIG. 9 is a cross-sectional view of a display device according to another exemplary embodiment.

The exemplary embodiment shown in FIG. 9 is substantially the same as the exemplary embodiment shown in FIG. 8 except for the second transistor TRa that is the switching transistor Qs such that the repeated description is omitted.

As shown in FIG. 9, in the display device according to another exemplary embodiment of the present disclosure, the second transistor TRb may be the switching transistor Qs and the first transistor TRa may be the driving transistor Qd.

The pixel electrode 710 is electrically connected to the first source electrode 173a of the first transistor TRa, thereby being the anode of the light emitting diode (LED). Since the first buffer layer 121 including a silicon oxide (SiOx) is only positioned under the oxide semiconductor 130b of the second transistor TRb, hydrogen may be minimized from inflowing into the oxide semiconductor 130b. Accordingly, the characteristic change of the second transistor TRb may be minimized.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A transistor array panel comprising:
a substrate;
a first buffer layer positioned on the substrate; and
a first transistor and a second transistor positioned on the substrate and separated from each other,
wherein the first transistor includes
a polycrystalline semiconductor positioned on the substrate, and
a first gate electrode overlapping the polycrystalline semiconductor, and the second transistor includes
an oxide semiconductor positioned on the first buffer layer, and
a second gate electrode overlapping the oxide semiconductor,
wherein the first buffer layer covers the first gate electrode, and
the first buffer layer includes a silicon oxide.

2. The transistor array panel of claim 1, further comprising:
a first insulating layer positioned between the polycrystalline semiconductor and the first gate electrode;
a second insulating layer positioned on the first buffer layer; and
an insulating member positioned between the oxide semiconductor and the second gate electrode, and
wherein the second insulating layer and the insulating member include the same material.

3. The transistor array panel of claim 2, further comprising
a third insulating layer positioned on the second insulating layer and the second gate electrode,
wherein the first transistor further includes a first source electrode and a first drain electrode that are positioned on the third insulating layer and are connected to the polycrystalline semiconductor, and
the second transistor further includes a second source electrode and a second drain electrode that are positioned on the third insulating layer and are connected to the oxide semiconductor.

4. The transistor array panel of claim 2, further comprising
a second buffer layer positioned between the substrate and the polycrystalline semiconductor, and
wherein the second buffer layer includes a silicon nitride.

5. The transistor array panel of claim 4, wherein
the second buffer layer extends to a bottom of the first buffer layer, and
the second buffer layer includes a silicon nitride.

6. The transistor array panel of claim 5, wherein
the first insulating layer extends to a bottom of the first buffer layer, and
the first insulating layer includes a silicon nitride.

7. The transistor array panel of claim 3, further comprising:
a storage electrode overlapping the first gate electrode; and
a storage layer positioned between the first gate electrode and the storage electrode,
wherein the storage electrode is positioned under the first buffer layer.

8. A transistor array panel comparing:
a substrate;
a first buffer layer positioned on the substrate;
a second buffer layer positioned on the first buffer layer; and
a first transistor and a second transistor positioned on the first buffer layer and separated from each other,
wherein the first transistor includes
a polycrystalline semiconductor positioned on the second buffer layer, and
a first gate electrode overlapping the polycrystalline semiconductor, the second transistor includes
an oxide semiconductor positioned on the first buffer layer, and
a second gate electrode overlapping the oxide semiconductor,
wherein the second buffer layer covers the second gate electrode, and
the first buffer layer includes a silicon oxide.

9. The transistor array panel of claim 8, further comprising:
a first insulating layer positioned between the polycrystalline semiconductor and the first gate electrode; and
an insulating member positioned between the oxide semiconductor and the second gate electrode, and
wherein the insulating member is positioned under the first insulating layer.

10. The transistor array panel of claim 9, further comprising
a third insulating layer covering the first insulating layer and the first gate electrode,
wherein the first transistor further includes a first source electrode and a first drain electrode that are positioned on the third insulating layer and are connected to the polycrystalline semiconductor, and
the second transistor further includes a second source electrode and a second drain electrode that are positioned on the third insulating layer and are connected to the oxide semiconductor.

11. The transistor array panel of claim 10, wherein
the second buffer layer includes a silicon nitride.

12. The transistor array panel of claim 10, further comprising:
a storage electrode overlapping the first gate electrode; and
a storage layer positioned between the first gate electrode and the storage electrode, and
wherein the storage electrode is positioned under the third insulating layer.

13. A display device comprising:
a substrate;
a first buffer layer positioned on the substrate;
a first transistor and a second transistor positioned on the substrate and separated from each other;
a first electrode connected to one of the first transistor and the second transistor;
a second electrode facing the first electrode; and
a light emission member positioned between the first electrode and the second electrode,
wherein the first transistor includes
a polycrystalline semiconductor positioned on the substrate, and
a first gate electrode overlapping the polycrystalline semiconductor, and the second transistor includes
an oxide semiconductor positioned on the first buffer layer, and
a second gate electrode overlapping the oxide semiconductor,
wherein the first buffer layer covers the first gate electrode, and
the first buffer layer includes a silicon oxide.

14. The display device of claim 13, further comprising:
a first insulating layer positioned between the polycrystalline semiconductor and the first gate electrode;
a second insulating layer positioned on the first buffer layer; and
an insulating member positioned between the oxide semiconductor and the second gate electrode, and
wherein the second insulating layer and the insulating member include the same material.
